(19) United States
(12) Patent Application Publication
(10) Pub. No.: US 2025/0143040 A1
(43) Pub. Date: May 1, 2025

(54) MICRO-LIGHT EMITTING DEVICE AND DISPLAY DEVICE HAVING THE SAME

(71) Applicant: Quanzhou Sanan Semiconductor Technology Co., Ltd., Quanzhou (CN)

(72) Inventors: Jing WANG, Tianjin (CN); Yang YANG, Quanzhou (CN)

(21) Appl. No.: 18/919,879

(22) Filed: Oct. 18, 2024

(30) Foreign Application Priority Data
Oct. 31, 2023 (CN) 202311435026.4

(51) Int. Cl. H01L 33/60; H01L 27/15

(52) U.S. Cl. CPC H10H 20/856; H10H 29/142

(57) ABSTRACT

A micro light-emitting device includes a semiconductor epitaxial structure, a convex lens structure, and a light-reflecting structure. The semiconductor epitaxial structure includes a first semiconductor layer, an active layer, and a second semiconductor layer that are sequentially stacked in such order. The convex lens structure is disposed on a light-exiting side of the semiconductor epitaxial structure and has a lens bottom connected thereof. The convex lens structure protrudes outward in a direction corresponding to a direction along which light exits. The light-reflecting structure is disposed at an outer surface of the convex lens structure proximate to the lens bottom. The light-reflecting structure having a light-reflecting surface that faces the outer surface of the convex lens structure. A display device includes a driver substrate and a pixel unit including a plurality of the micro light-emitting devices above. The micro light-emitting devices are arranged in an array on the driver substrate.

### CROSS-REFERENCE TO RELATED APPLICATION

This application claims priority to Chinese Invention Patent Application No. CN202311435026.4, filed on Oct. 31, 2023, and incorporated by reference herein in its entirety.

### FIELD

The disclosure relates to a micro light-emitting device and more particularly to a micro light-emitting device and a display device including many micro light-emitting devices.

### BACKGROUND

Micro light-emitting diodes (LEDs) have characteristics such as small size, dense packaging, and intrinsic self-illumination. When compared to liquid crystal displays (LCDs) and organic light-emitting diodes (OLEDs), micro LEDs have advantages such as higher brightness, higher contrast ratio, higher color gamut, faster response times, better efficiency, and longer lifetime. Micro LEDs have found wide applications commercially; particularly, in the fields of augmented reality (AR) and virtual reality (VR), and have found application in wearable devices, head up displays (HUDs), mini projectors, and 3D printers etc. Moreover, micro LEDs have been endorsed as a technical solution for near-eye displays (NEDs) in VR/AR applications.

Market demand for micro LEDs have continuously expanded as commercial demand for AR/VR devices increases. With the increasing pursuit of smaller and lighter size, micro LEDs have shrunk in size, and chip sizes have decreased to 5 μm, 2 μm and even to under 2 μm.

When micro LEDs are applied in AR/VR products, axial brightness is a very important consideration. Currently, micro LEDs use refraction via a micro lens to converge light in each micro LED. The micro lens is usually made of a transparent medium and designed to be a suitable shape that may converge as much light as possible towards the axial direction of the micro LED. However, when incident light is highly angled it may be difficult to design a suitable shape that may converge the light towards the axial direction.

### SUMMARY

Therefore, an object of the disclosure is to provide a micro light-emitting device and a display device that can alleviate at least one of the drawbacks of the prior art.

According to the disclosure one aspect of the disclosure, the micro light-emitting device includes a semiconductor epitaxial structure, a convex lens structure, and a light-reflecting structure. The semiconductor epitaxial structure includes a first semiconductor layer, an active layer, and a second semiconductor layer that are sequentially stacked in such order. The convex lens structure is disposed on a light-exiting side of the semiconductor epitaxial structure and has a lens bottom connected to the semiconductor epitaxial structure. The convex lens structure protrudes outward in a direction that corresponds to a direction along which light exits from the light-exiting side. The light-reflecting structure is disposed at an outer surface of the convex lens structure proximate to the lens bottom. The light-reflecting structure has a light-reflecting surface that faces the outer surface of the convex lens structure.

In another aspect of the disclosure, the display device includes a driver substrate and a pixel unit. The pixel unit includes a plurality of the micro light-emitting devices as described above. The micro light-emitting devices are arranged in an array on the driver substrate. The pixel unit further includes a plurality of chiplet isolation slots that are each disposed between two adjacent ones of the micro light-emitting devices.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a first embodiment of the present disclosure which is a micro light-emitting device.

FIG. 2 is a schematic cross-sectional view illustrating a convex lens structure and a light-reflecting structure of the micro light-emitting device.

FIG. 3 is a fragmentary schematic cross-sectional view illustrating a second embodiment of the present disclosure which is a display device.

FIG. 4 is a fragmentary schematic cross-sectional view illustrating a third embodiment of the present disclosure which is another display device.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

### First Embodiment

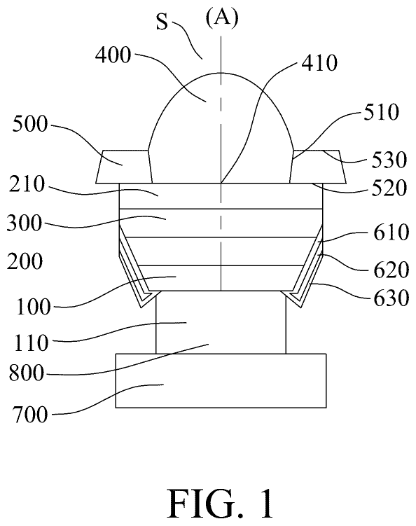

Referring to FIGS. 1, in a first embodiment of the present disclosure a micro light-emitting device includes a semiconductor epitaxial structure, a convex lends structure 400, and a light-reflecting structure 500. The semiconductor epitaxial structure includes a first semiconductor layer 100, an active layer 200, and a second semiconductor layer 300 that are sequentially stacked in such order.

In some embodiments, the first semiconductor layer 100 may be an N-type semiconductor layer which provides electrons to the active layer 200 when powered under a current. In some embodiments, the first semiconductor layer 100 may include an N-type doped nitride layer. This N-type doped nitride layer may include one of N-type dopants such as Si, Ge, and Sn, or a combination of the above. The first type semiconductor layer 100 may be a single layered structure or may be a multi-layered structure.

The second semiconductor layer 300 may be a P-type semiconductor layer which provides holes to the active layer 200 when powered under a current. In some embodiments, the second semiconductor layer 300 may include a P-type doped nitride layer. This P-type doped nitride layer may include a one or more P-type dopants. The P-type dopant may be one of Mg, Zn, and Be, or a combination of the above. The second semiconductor layer 300 may be a single layered structure or a multilayered structure that has different compositions.

Additionally, in some embodiments, the first semiconductor layer 100 may be a P-type semiconductor layer, and the second semiconductor layer 300 may be an N-type semiconductor layer.

The active layer 200 may be a quantum well structure. In some embodiments, the active layer 200 may be a multiple quantum well structure, where multiple wells layers and multiple barrier layers are alternately arranged. For example, the active layer 200 may be a multiple quantum well structure such as GaN/AlGaN, InAlGaN/InAlGaN or InGaN/AlGaN. It should be noted that the wavelength of light emitted from the active layer 200 is decided by the composition and thickness of the well layers and the barrier layers. In order to increase light emission efficiency, specific characteristics of the active layer 200 may be adjusted, for example, the number of pairs of well layers and barrier layers, or the thickness of the well layers and barrier layers.

The convex lens structure 400 is disposed on a light-exiting side (S) of the semiconductor epitaxial structure and has a lens bottom 410 connected to the semiconductor epitaxial structure. The convex lens structure 400 protrudes outward in a direction that corresponds to a direction along which light exists from the light-exiting side (S). Referring to FIG. 1, in the first embodiment, the light-exiting side (S) is a side of the semiconductor epitaxial structure where the second semiconductor layer 300 is situated. By virtue of having the convex lens structure 400 disposed on the light-exiting side (S) of the semiconductor epitaxial structure, light rays emitted from the active layer 200 that are not perpendicular to the surface of the second semiconductor layer 300 may be refracted and reflected toward an axis (A) of the convex lens structure 400 which is shown in the dotted line in FIG. 1 so that the light rays converge and improve light emission of the micro light-emitting device along the axis (A).

Referring to FIG. 1, the light-reflecting structure 500 is disposed at an outer surface of the convex lens structure 400 proximate to the lens bottom 410. The light-reflecting structure 500 has a light-reflecting surface 510 that faces the outer surface of the convex lens structure 400. The light-reflecting surface 510 of the light-reflecting structure 500 reflects incident light that is too highly angled relative to the axis (A) and converges light towards the axis (A) of the convex lens structure 400 to increase axial luminous intensity and enhance light emission of the micro light-emitting device along the axis (A).

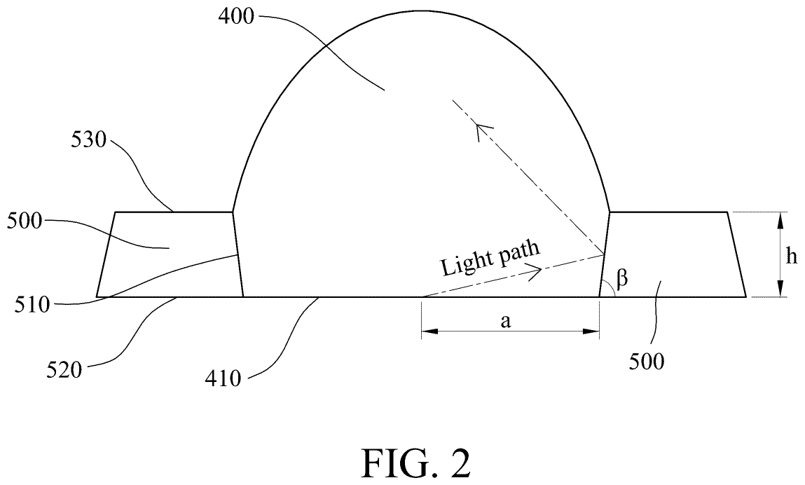

Referring to FIGS. 1 and 2, the light-reflecting structure 500 has a light-reflecting structure bottom surface 520 connected to the semiconductor epitaxial structure and a light-reflecting structure top surface 530 opposite to the light-reflecting structure bottom surface 520. A cross-section of the light-reflecting structure 500 perpendicular to the axis (A) decreases in area in a direction from the light-reflecting structure bottom surface 520 to the light-reflecting structure top surface 530. In this embodiment, the cross-section of the light-reflecting structure 500 is an isosceles trapezoid. The light-reflecting surface 510 of the light-reflecting structure 500 is able to reflect incident light that is too highly angled relative to the axis (A) and converge light towards the axis of the convex lens structure 400. Furthermore, the light-reflecting surface 510 ensures that the incident light thus reflected is emitted from the light-exiting side (S) of the micro light-emitting device. In some embodiments, the light-reflecting structure 500 may be a continuous integrated structure that surrounds and forms a loop around the lens bottom 410 of the convex lens structure 400. In other embodiments, the light-reflecting structure 500 may be composed of several block structures disposed around the lens bottom 410 of the convex lens structure 400.

Referring to FIG. 2, in some embodiments, an angle (β) is formed between the light-reflecting surface 510 and the light-reflecting structure bottom surface 520. The angle (β) ranges from 45° to 75° and helps to greatly increase the light converging effect of the micro light-emitting device. If the angle (β) is too small, the incident light will experience only a minor change in direction after being reflected, and incident light that is too highly angled relative to the axis (A) cannot be converged toward the axis. On the other hand, if the angle (β) is too large, the incident light will be directed in a direction opposite the light-exiting side (S) and will be almost parallel to the light-reflecting surface 510 after reflection, thereby making light convergence in the micro light-emitting device more difficult to achieve. The angle (β) may be designed according to the amount of light convergence required. For example, in some embodiments, the angle (β) may range from 40° to 80°. In other embodiments, the angle (β) may range from 30° to 85°.

In some embodiments, in order to increase the light convergence effect of the convex lens structure 400, a ratio of a radius (a) of the convex lens structure 400 to a height (h) of the light-reflecting structure 500 may range from 1:1 to 1.25:1. Referring to FIG. 2, the radius (a) of the convex lens structure 400 is a minimum distance from a peripheral edge of the lens bottom 410 of the convex lens structure 400 to the axis (A) of the convex lens structure 400. The height (h) of the light-reflecting structure 500 is a minimum distance between the light-reflecting structure bottom surface 520 and the light-reflecting structure top surface 530.

The light-reflecting structure 500 may be made of a metallic material or have a DBR structure. The light-reflecting structure 500 may be made of a metallic material selected from at least one of Au, Ag, Al, and Cu. The light-reflecting structure 500 may be a DBR structure composed from alternating layers of high reflective sublayers and low reflective sublayers. The high reflective sublayers may be made of silicon nitride, silicon oxynitride, aluminum oxide, or titanium oxide. The low reflective sublayers may be made of silicon oxide.

When the light-reflecting structure 500 is made of a metallic material, the metallic material not only has better light reflecting properties, but also provides current spreading so that the electric current is distributed more evenly, thereby increasing the performance of the micro light-emitting diode. In some embodiments, the micro light-emitting device may have additional characteristics such as having an ohmic contact layer, a current spreading layer, or a patterned surface.

### Second Embodiment

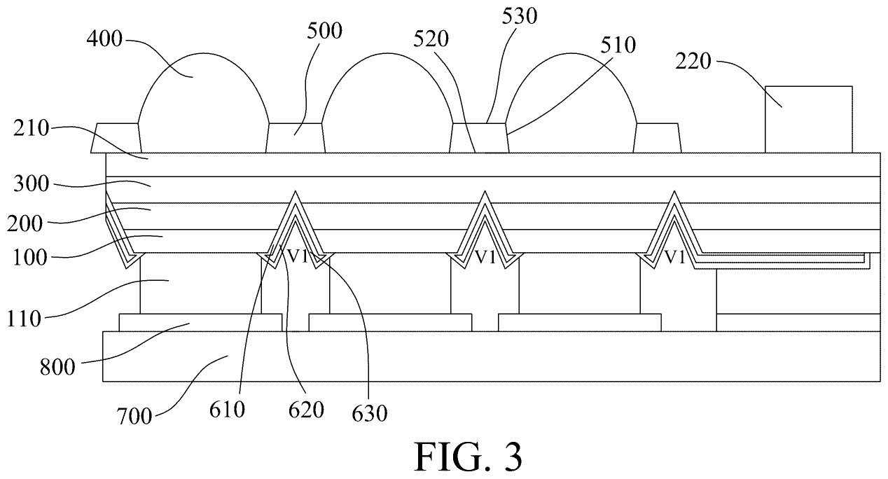

Referring to FIG. 3, a second embodiment of the present disclosure is a display device including a driver substrate 700 and a pixel unit. The pixel unit includes a plurality of the micro light-emitting devices of the first embodiment. The micro light-emitting devices are arranged in an array on the driver substrate 700. In this embodiment, the first semiconductor layer 100 of each of the micro light-emitting devices is an N-type semiconductor layer, and the second semiconductor layer 300 of each of the micro light-emitting devices is a P-type semiconductor layer.

The pixel unit further includes a plurality of chiplet isolation slots (V1) that are each disposed between two adjacent ones of the micro light-emitting devices. Each of the chiplet isolation slots (V1) extends from the first semiconductor layer 100, passes through the active layer 200 and then penetrates into the second semiconductor layer 300. However, in this embodiment, the chiplet isolation slots (V1) penetrate into a portion of the second semiconductor layer 300; but does not penetrate through an entire thickness of the second semiconductor layer 300. In this embodiment, each of the semiconductor epitaxial structures of the micro light-emitting devices has a cross-sectional area perpendicular to a thickness direction of the semiconductor epitaxial structures; the cross-sectional area is gradually enlarged from the first semiconductor layer 100 to the second semiconductor layer 300. In other words, in this embodiment the semiconductor epitaxial structures are roughly trapezoidal in shape. In other embodiments, each of the cross-sectional areas of the semiconductor epitaxial structures is unchanged from the first semiconductor layer 100 to the second semiconductor layer 300.

Referring to FIG. 3, in this embodiment, the micro light-emitting devices include second semiconductor layers 300 that are connected as a continuous structure. In some embodiments, each of the micro light-emitting devices further includes a transparent conductive layer 210 that is disposed on the second semiconductor layer 300 away from the active layer 200. The transparent conductive layer 210 of the micro light-emitting devices are connected together as a continuous structure. Furthermore, the lens bottom 410 of the convex lens structure 400 and the light-reflecting structure bottom surface 520 of the light-reflecting structure 500 are in contact with the transparent conductive layer 210. The transparent conductive layer 210 may be made of a material including indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), or tungsten doped indium oxide (IWO). However, the disclosure in not limited in this respect and other choices of materials are possible.

In this embodiment, each of the light-reflecting structures 500 of the micro light-emitting devices are disposed in spacings formed between the convex lens structures 400 of adjacent ones of the micro light-emitting devices. The light-reflecting structures 500 of each of the micro light-emitting devices have side surfaces each forming the light-reflecting surface 510. The light-reflecting surfaces 510 of the light-reflecting structures 500 of the micro light-emitting devices are proximate to lens bottoms 410 of the convex lens structures 400 of the micro light-emitting devices and contact the outer surfaces of the convex lens structures 400. By having the light-reflecting structures 500 disposed in spacings between the convex lens structures 400 of adjacent micro light-emitting devices, each light-reflecting structure 500 may be shared between convex lens structures 400 of two adjacent micro light-emitting devices, thereby saving space and allowing the display device to be made smaller.

In some embodiments, each of the micro light-emitting devices further includes a first pad electrode 110 that is disposed on the first semiconductor layer 100, and a first insulation layer 610 that covers a portion of a sidewall of the first pad electrode 110, a sidewall of the first semiconductor layer 100, a sidewall of the active layer 200, and a portion of a sidewall of the second semiconductor layer 200. Each of the micro light-emitting devices further includes a bonding layer 800 that is disposed on the first pad electrode 110, each of the micro light-emitting devices are electrically connected to the driver substrate 700 via the bonding layer 800. The driver substrate 700 may be a silicon based CMOS driver board or other types of drivers as required. Referring to FIGS. 1 and 3, each of the micro light-emitting devices further includes a mirror layer 620 and a second insulation layer 630 that are sequentially disposed on an outer surface of the first insulation layer 610.

The first and second insulation layers 610, 630 include a non-conductive material that may be an inorganic material or a dielectric material. For example, the dielectric material may be an insulating material such as aluminum oxide, silicon nitride, silicon oxide, titanium oxide, or magnesium fluoride. In some embodiments, the first and second insulation layers 610, 630 may be made of silicon dioxide, silicon nitride, titanium oxide, tantalum oxide, niobium oxide, barium titanate, a combination, or combinations of the above. In some embodiments, the first insulation layer 610, the mirror layer 620, and the second insulation layer 630 may form an omni-directional reflector (ODR).

Referring to FIG. 3, the transparent conductive layer 210 is formed with a second pad electrode 220. Moreover, various characteristics of the display device may be changed according to requirements.

### Third Embodiment

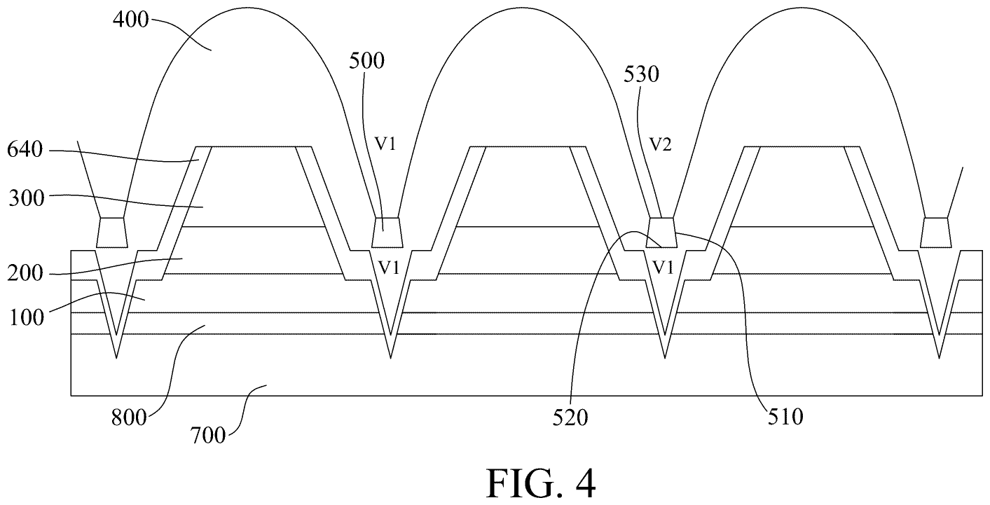

Referring to FIG. 4, a third embodiment of the present disclosure is a display device similar to the second embodiment. The display device includes the driver substrate 700 and the pixel unit. The pixel unit includes a plurality of micro light-emitting devices of the first embodiment that are arranged in an array on the driver substrate 700. However, the third embodiments is different from the second embodiment in that, the first semiconductor layer 100 of each of the micro light-emitting devices is a P-type semiconductor layer, and the second semiconductor layer 300 of each of the micro light-emitting devices is an N-type semiconductor layer. Furthermore, the semiconductor epitaxial structure of each of the micro light-emitting devices has a cross-sectional area perpendicular to a thickness direction of the semiconductor epitaxial structures. The cross-sectional area is gradually enlarged from the second semiconductor layer 300 to the first semiconductor layer 100. In other words, the semiconductor epitaxial structure of each of the micro light-emitting devices are shaped like an isosceles trapezoid. However, in other embodiments, the cross-sectional area of the semiconductor epitaxial structure of each of the micro light-emitting devices may be unchanged from the second semiconductor layer 300 to the first semiconductor layer 100.

Each of the chiplet isolation slots (V1) extends from the first semiconductor layer 100, passes through the active layer 200 and then penetrates into the second semiconductor layer 300. Particularly, in this embodiment, the chiplet isolation slots (V1) penetrates through an entire thickness of the second semiconductor layer 300. The pixel unit further has a plurality of lens gaps (V2) each of which is formed between adjacent ones of the convex lens structures 400 of the micro light-emitting devices.

Referring to FIG. 4, each of the micro light-emitting devices further includes a third insulation layer 640 that covers a sidewall of the second semiconductor layer 300, a side wall of the active layer 200, and a side wall of the first semiconductor layer 100.

For each of the micro light-emitting devices, the convex lens structure 400 is disposed outside of the third insulation layer 640, and envelops the semiconductor epitaxial structure. The convex lens structure 400 is disposed on the light-exiting side (S) of the semiconductor epitaxial structure and protrudes outward in a direction corresponding to a direction along which light exits, thereby providing a light converging effect.

Referring to FIG. 4, in this embodiment, each of the lens gaps (V2) corresponds in position to one of the chiplet isolation slots (V1). In other words the lens gaps (V2) formed between adjacent ones of the convex lens structures (400) of the micro light-emitting devices are respectively aligned with the chiplet isolation slots (V1) that are disposed between adjacent ones of the micro light-emitting devices.

Furthermore, each of the micro light-emitting devices includes a bonding layer 800 disposed on a side of the first semiconductor layer 100 away from said active layer 200. Each of the micro light-emitting devices are electrically connected to the driver substrate 700 via the bonding layer 800.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A micro light-emitting device, comprising:
a semiconductor epitaxial structure including a first semiconductor layer, an active layer, and a second semiconductor layer that are sequentially stacked in such order;
a convex lens structure that is disposed on a light-exiting side of said semiconductor epitaxial structure and that has a lens bottom connected to said semiconductor epitaxial structure, said convex lens structure protruding outward in a direction that corresponds to a direction along which light exits from said light-exiting side; and
a light-reflecting structure that is disposed at an outer surface of said convex lens structure proximate to said lens bottom, said light-reflecting structure having a light-reflecting surface that faces said outer surface of said convex lens structure.

2. The micro light-emitting device as claimed in claim 1, wherein:
said light-reflecting structure has a light-reflecting structure bottom surface connected to said semiconductor epitaxial structure, and a light-reflecting structure top surface opposite to said light-reflecting structure bottom surface; and
a cross-section of said light-reflecting structure perpendicular to an axis (A) of said convex lens structure decreases in area in a direction from said light-reflecting structure bottom surface to said light-reflecting structure top surface.

3. The micro light-emitting device as claimed in claim 2, wherein an angle (β) that is formed between said light-reflecting surface and said light-reflecting structure bottom surface ranges from 45° to 75°.

4. The micro light-emitting device as claimed in claim 1, wherein:
a ratio of a radius (a) of said convex lens structure to a height (h) of said light-reflecting structure ranges from 1:1 to 1.25:1;
said radius (a) of said convex lens structure is a minimum distance from a peripheral edge of said lens bottom of said convex lens structure to an axis (A) of said convex lens structure; and
said height (h) of said light-reflecting structure is a minimum distance between said light-reflecting structure bottom surface and said light-reflecting structure top surface.

5. The micro light-emitting device as claimed in claim 1, wherein said light-reflecting structure is made of a metallic material or has a DBR structure, said metallic material being selected from at least one of Au, Ag, Al and Cu.

6. A display device comprising:
a driver substrate and a pixel unit, said pixel unit including a plurality of said micro light-emitting devices as claimed in claim 1, said micro light-emitting devices being arranged in an array on said driver substrate; and
said pixel unit further including a plurality of chiplet isolation slots that are each disposed between two adjacent ones of said micro light-emitting devices.

7. The display device as claimed in claim 6, wherein each of said chiplet isolation slots extends from said first semiconductor layer, passes through said active layer and then penetrates into said second semiconductor layer.

8. The display device as claimed in claim 6, wherein said first semiconductor layer of each of said micro light-emitting devices is an N-type semiconductor layer, and said second semiconductor layer of each of said micro light-emitting devices is a P-type semiconductor layer, said micro light-emitting devices including said second semiconductor layers that are connected as a continuous structure, each of said semiconductor epitaxial structures of said micro light-emitting devices having a cross-sectional area perpendicular to a thickness direction of said semiconductor epitaxial structures, said cross-sectional area being gradually enlarged from said first semiconductor layer to said second semiconductor layer, or being unchanged from said first semiconductor layer to said second semiconductor layer.

9. The display device as claimed in claim 8, wherein:
said light-reflecting structures of said micro light-emitting devices are disposed in spacings formed between said convex lens structures of adjacent ones of said micro light-emitting devices;
said light-reflecting structure of each of said micro light-emitting devices having side surfaces each forming said light-reflecting surface; and
said light-reflecting surfaces of said light-reflecting structures of said micro light-emitting devices are proximate to said lens bottoms of said convex lens structures of said micro light-emitting devices and contact said outer surfaces of said convex lens structure.

10. The display device as claimed in claim 8, wherein each of said micro light-emitting devices further includes a first pad electrode that is disposed on said first semiconductor layer, and a first insulation layer that covers a portion of a sidewall of said first pad electrode, a sidewall of said first semiconductor layer, a sidewall of said active layer, and a portion of a sidewall of said second semiconductor layer.

11. The display device as claimed in claim 10, wherein each of said micro light-emitting devices further includes a mirror layer and a second insulation layer that are sequentially disposed on an outer surface of said first insulation layer.

12. The display device as claimed in claim 10, wherein each of said micro light-emitting devices further includes a bonding layer that is disposed on said first pad electrode, each of said micro light-emitting devices being electrically connected to said driver substrate via said bonding layer.

13. The display device as claimed in claim 10, wherein:
each of said micro light-emitting devices further includes a transparent conductive layer that is disposed on said second semiconductor layer away from said active layer, said transparent conductive layers of said micro light-emitting devices being connected together as a continuous structure;
said light-reflecting structure has a light-reflecting structure bottom surface;
said lens bottom of said convex lens structure and said light-reflecting structure bottom surface of said light-reflecting structure are in contact with said transparent conductive layer; and
said transparent conductive layer is formed with a second pad electrode.

14. The display device as claimed in claim 6, wherein said first semiconductor layer of each of said micro light-emitting devices is a P-type semiconductor layer, and said second semiconductor layer of each of said micro light-emitting devices is an N-type semiconductor layer, each of said semiconductor epitaxial structures of said micro light-emitting devices having a cross-sectional area perpendicular to a thickness direction of said semiconductor epitaxial structures, said cross-sectional area being enlarged from said second semiconductor layer to said first semiconductor layer, or being unchanged from said second semiconductor layer to said first semiconductor layer.

15. The display device as claimed in claim 14, wherein:
each of said micro light-emitting devices further includes a third insulation layer that covers a sidewall of said second semiconductor layer, a sidewall of said active layer, and a side wall of said first semiconductor layer; and
for each of said micro light-emitting devices, said convex lens structure is disposed outside of said third insulation layer.

16. The display device as claimed in claim 14, wherein said pixel unit further has a plurality of lens gaps each of which is formed between adjacent ones of said convex lens structures of said micro light-emitting devices and each of which corresponds in position to one of said chiplet isolation slots.

17. The display device as claimed in claim 14, wherein:
each of said micro light-emitting devices includes a bonding layer disposed on a side of said first semiconductor layer away from said active layer; and
each of said micro light-emitting devices being electrically connected to said driver substrate via said bonding layer.
